(19) United States
(12) Patent Application Publication
(10) Pub. No.: US 2026/0227551 A1
(43) Pub. Date: Aug. 6, 2026

(54) WINDOW MODULE, DISPLAY DEVICE INCLUDING THE WINDOW MODULE, AND ELECTRONIC DEVICE INCLUDING THE WINDOW MODULE

(71) Applicant: Samsung Display Co., LTD., Yongin-si (KR)

(72) Inventors: DAHYE KIM, Yongin-si (KR); MANSOO KIM, Yongin-si (KR); JUNGHYUN KIM, Yongin-si (KR); HYUN-HYANG KIM, Yongin-si (KR); JUYOUNG YOON, Yongin-si (KR); HYEONMI LEE, Yongin-si (KR)

(21) Appl. No.: 19/384,172

(22) Filed: Nov. 10, 2025

(30) Foreign Application Priority Data
Feb. 5, 2025 (KR) 10-2025-0014284

(51) Int. Cl. G02B 1/115; G02B 1/14; G06F 1/16

(52) U.S. Cl. CPC G02B 1/115; G02B 1/14; G06F 1/1656

(57) ABSTRACT

A window module includes a base substrate and an anti-reflection layer. The anti-reflection layer includes a plurality of first refractive layers located on the base substrate, including a first inorganic material and having a first refractive index, a plurality of second refractive layers located between the first refractive layers, including a second inorganic material and having a second refractive index greater than the first refractive index, and a plurality of third refractive layers located between the first refractive layers and the second refractive layers, including a third inorganic material and having a third refractive index greater than the first refractive index and less than the second refractive index.

This application claims priority to Korean Patent Application No. 10-2025-0014284, filed on Feb. 5, 2025, and all the benefits accruing therefrom under 35 U.S.C. § 119, the content of which in its entirety is herein incorporated by reference.

### BACKGROUND

### 1. Field

Embodiments relate to a window module, a display device including the window module, and an electronic device including the window module.

### 2. Description of the Related Art

A display device may include a display panel and a window module located on the display panel to protect the display panel. As various forms of display devices are being used, various forms of window modules may be implemented for the display devices. In some cases, structures capable of enhancing the durability of the display device and reducing reflectivity are being developed in order to improve the display quality of the display device.

### SUMMARY

Embodiments provide a window module having improved optical characteristics and durability.

Embodiments provide a display device including the window module.

Embodiments provide an electronic device including the display device.

A window module according to embodiments of the present disclosure includes a base substrate and an anti-reflection layer. The anti-reflection layer may include a plurality of first refractive layers located on the base substrate, including a first inorganic material, and having a first refractive index, a plurality of second refractive layers located between the first refractive layers, including a second inorganic material, and having a second refractive index greater than the first refractive index, and a plurality of third refractive layers located between the first refractive layers and the second refractive layers, including a third inorganic material, and having a third refractive index greater than the first refractive index and less than the second refractive index.

In an embodiment, the first refractive index of each of the first refractive layers may range from about 1.45 to about 1.5.

In an embodiment, the second refractive index of each of the second refractive layers may range from about 1.95 to about 2.1.

In an embodiment, the third refractive index of each of the third refractive layers may range from about 1.54 to about 1.7.

In an embodiment, the first inorganic material may include at least one selected from a group consisting of silicon dioxide (SiO₂), silicon oxide (SiOₓ), silicon oxynitride (SiOₓN_{y}), silicon aluminum oxide (SiₓAl_{y}O_{z}), magnesium fluoride (MgF₂), magnesium oxide (MgO), and germanium oxide (GeOₓ).

In an embodiment, the second inorganic material may include at least one selected from a group consisting of silicon nitride (Si₃N₄), aluminum nitride (AlN), silicon aluminum nitride (SiAlₓN_{y}), germanium nitride (GeNₓ), silicon germanium nitride (SiGeₓN_{y}), tantalum pentoxide (Ta₂O₅), titanium dioxide (TiO₂), and zirconium dioxide (ZrO₂).

In an embodiment, the third inorganic material may include at least one selected from a group consisting of aluminum oxide (Al₂O₃), aluminum oxynitride (AlOₓN_{y}), silicon oxynitride (SiOₓN_{y}), and silicon-aluminum oxynitride (SiAlₓO_{y}N_{z}).

In an embodiment, the third inorganic material may have a hardness greater than a hardness of the first inorganic material and less than a hardness of the second inorganic material.

In an embodiment, the first refractive layers may include a 1-1 refractive layer, a 1-2 refractive layer located on the 1-1 refractive layer, and a 1-3 refractive layer located on the 1-2 refractive layer. The second refractive layers may include a 2-1 refractive layer, a 2-2 refractive layer located on the 2-1 refractive layer, and a 2-3 refractive layer located on the 2-2 refractive layer. The third refractive layers may include a 3-1 refractive layer, a 3-2 refractive layer located on the 3-1 refractive layer, and a 3-3 refractive layer located on the 3-2 refractive layer.

In an embodiment, the 1-1 refractive layer, the 3-1 refractive layer, the 1-2 refractive layer, the 2-1 refractive layer, the 3-2 refractive layer, the 2-2 refractive layer, the 3-3 refractive layer, the 2-3 refractive layer, and the 1-3 refractive layer may be sequentially located on the base substrate.

In an embodiment, a thickness of the 1-1 refractive layer may range from about 20 nm to about 40 nm. A thickness of the 1-2 refractive layer may range from about 50 nm to about 70 nm. A thickness of the 1-3 refractive layer may range from about 95 nm to about 105 nm. A thickness of the 2-1 refractive layer may range from about 20 nm to about 30 nm. A thickness of the 2-2 refractive layer may range from about 80 nm to about 100 nm. A thickness of the 2-3 refractive layer may range from about 45 nm to about 55 nm. A thickness of the 3-1 refractive layer may range from about 20 nm to about 40 nm. A thickness of the 3-2 refractive layer may range from about 45 nm to about 65 nm. A thickness of the 3-3 refractive layer may range from about 5 nm to about 20 nm.

In an embodiment, a thickness of the anti-reflection layer may range from about 400 nm to about 500 nm.

In an embodiment, a hardness of the window module may range from about 10 GPa to about 15 GPa.

In an embodiment, the base substrate may include a planar area and a curved area located on at least one side of the planar area and having a predetermined curvature.

In an embodiment, the window module may further include a hard coating layer located between the base substrate and the anti-reflection layer and an anti-fingerprint layer located on the anti-reflection layer.

A display device according to embodiments of the present disclosure includes a display panel, a window module located on the display panel, and an adhesive layer attaching the display panel and the window module. The window module includes a base substrate and an anti-reflection layer. The anti-reflection layer includes a plurality of first refractive layers located on the base substrate, including a first inorganic material, and having a first refractive index, a plurality of second refractive layers located between the first refractive layers, including a second inorganic material, and having a second refractive index greater than the first refractive index, and a plurality of third refractive layers located between the first refractive layers and the second refractive layers, including a third inorganic material, and having a third refractive index greater than the first refractive index and less than the second refractive index, and having a thickness in a range of about 400 nm to about 500 nm.

In an embodiment, the first refractive index of each of the first refractive layers may range from about 1.45 to about 1.5. The second refractive index of each of the second refractive layers may range from about 1.95 to about 2.1. The third refractive index of each of the third refractive layers may range from about 1.54 to about 1.7. The first inorganic material may include at least one selected from a group consisting of silicon dioxide (SiO₂), silicon oxide (SiOₓ), silicon oxynitride (SiOₓN_{y}), silicon aluminum oxide (SiₓAl_{y}O_{z}), magnesium fluoride (MgF₂), magnesium oxide (MgO), and germanium oxide (GeOₓ). The second inorganic material may include at least one selected from a group consisting of silicon nitride (Si₃N₄), aluminum nitride (AlN), silicon aluminum nitride (SiAlₓN_{y}), germanium nitride (GeNₓ), silicon germanium nitride (SiGeₓN_{y}), tantalum pentoxide (Ta₂O₅), titanium dioxide (TiO₂), and zirconium dioxide (ZrO₂). The third inorganic material may include at least one selected from a group consisting of aluminum oxide (Al₂O₃), aluminum oxynitride (AlOₓN_{y}), silicon oxynitride (SiOₓN_{y}), and silicon-aluminum oxynitride (SiAlₓO_{y}N_{z}).

In an embodiment, the first refractive layers may include a 1-1 refractive layer, a 1-2 refractive layer located on the 1-1 refractive layer, and a 1-3 refractive layer located on the 1-2 refractive layer. The second refractive layers may include a 2-1 refractive layer, a 2-2 refractive layer located on the 2-1 refractive layer, and a 2-3 refractive layer located on the 2-2 refractive layer. The third refractive layers may include a 3-1 refractive layer, a 3-2 refractive layer located on the 3-1 refractive layer, and a 3-3 refractive layer located on the 3-2 refractive layer.

In an embodiment, the 1-1 refractive layer, the 3-1 refractive layer, the 1-2 refractive layer, the 2-1 refractive layer, the 3-2 refractive layer, the 2-2 refractive layer, the 3-3 refractive layer, the 2-3 refractive layer, and the 1-3 refractive layer may be sequentially located on the base substrate.

An electronic device according to embodiments of the present disclosure includes a display device and a processor which controls the display device. The display device includes a display panel, a window module located on the display panel, and an adhesive layer attaching the display panel and the window module. The window module includes a base substrate and an anti-reflection layer. The anti-reflection layer includes a plurality of first refractive layers located on the base substrate, including a first inorganic material, and having a first refractive index, a plurality of second refractive layers located between the first refractive layers, including a second inorganic material, and having a second refractive index greater than the first refractive index, and a plurality of third refractive layers located between the first refractive layers and the second refractive layers, including a third inorganic material, and having a third refractive index greater than the first refractive index and less than the second refractive index.

A window module according to embodiments of the present disclosure may include a base substrate and an anti-reflection layer. The anti-reflection layer may include a plurality of first refractive layers, a plurality of second refractive layers, and a plurality of third refractive layers. A second refractive index of the second refractive layer may be greater than the first refractive layer, and a third refractive index of the third refractive layer may be greater than the first refractive index and less than the second refractive index. Accordingly, color difference occurring at the edge of the display device may be reduced.

In some aspects, a third inorganic material of the third refractive layer may have a hardness greater than a hardness of a first inorganic material of the first refractive layer and may have a hardness less than a hardness of a second inorganic material of the second refractive layer. Accordingly, a hardness of the window module may be improved.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment.

FIG. 2 is an exploded perspective view illustrating a part of the configuration of the display device according to an embodiment of the display device of FIG. 1.

FIG. 3 is a cross-sectional view schematically illustrating the display device of FIG. 1.

FIG. 4 is a cross-sectional view illustrating a display panel included in the display device of FIG. 1

FIG. 5 is a cross-sectional view of a window module taken along the line I-I′ of FIG. 2.

FIG. 6 is a cross-sectional view illustrating a base substrate of the window module of FIG. 5.

FIG. 7 is a cross-sectional view illustrating an anti-reflection layer of the window module of FIG. 5.

FIG. 8 is a cross-sectional view illustrating the anti-reflection layer of FIG. 3.

FIG. 9 is a block diagram illustrating an electronic device including the display device of FIG. 1.

FIG. 10 is a view illustrating an example in which the electronic device of FIG. 9 is implemented as a television.

FIG. 11 is a view illustrating an example in which the electronic device of FIG. 9 is implemented as a smartphone.

### DETAILED DESCRIPTION

Hereinafter, embodiments of the present disclosure will be described in more detail with reference to the accompanying drawings. In the drawings, the same reference numerals/characters are used for the same components in the drawings, and redundant descriptions of the same components will not be provided for conciseness.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

In this specification, a plane may be defined by a first direction D1 and a second direction D2 that intersects the first direction D1. For example, the second direction D2 may be perpendicular to the first direction D1. In some aspects, a third direction D3 may be a normal direction of the plane. That is, the third direction D3 may be perpendicular to the plane formed by the first direction D1 and the second direction D2.

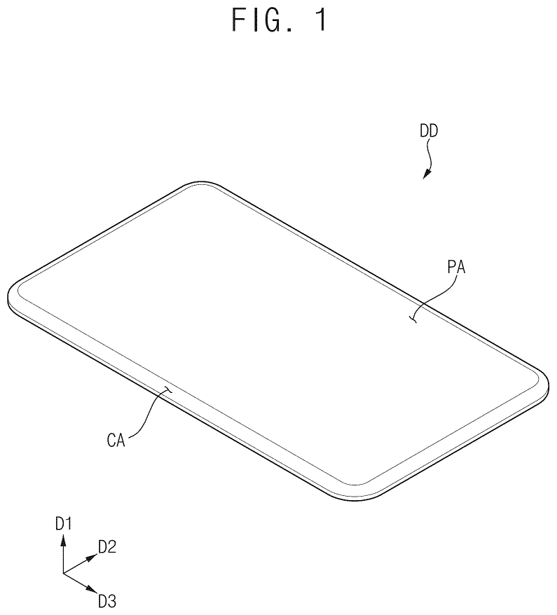

FIG. 1 is a perspective view illustrating a display device according to an embodiment.

Referring to FIG. 1, a display device DD may be a device activated according to an electrical signal. For example, the display device DD may be a mobile phone, a tablet or a wearable device, but the present disclosure is not necessarily limited thereto.

The display device DD according to an embodiment of the present disclosure may include a planar area PA and a curved area CA located on at least one side of the planar area PA and having a predetermined curvature. The curved area CA may be bent from each edge of the planar area PA with a predetermined curvature.

For example, as illustrated in FIG. 1, all portions of the display device DD located at the edge of the planar area PA may be defined as the curved area CA. At this time, curvatures of the curved area CA may be the same or different from each other. However, the present disclosure is not necessarily limited thereto.

For example, a portion of the display device DD located at the edge of the planar area PA may be defined as the curved area CA.

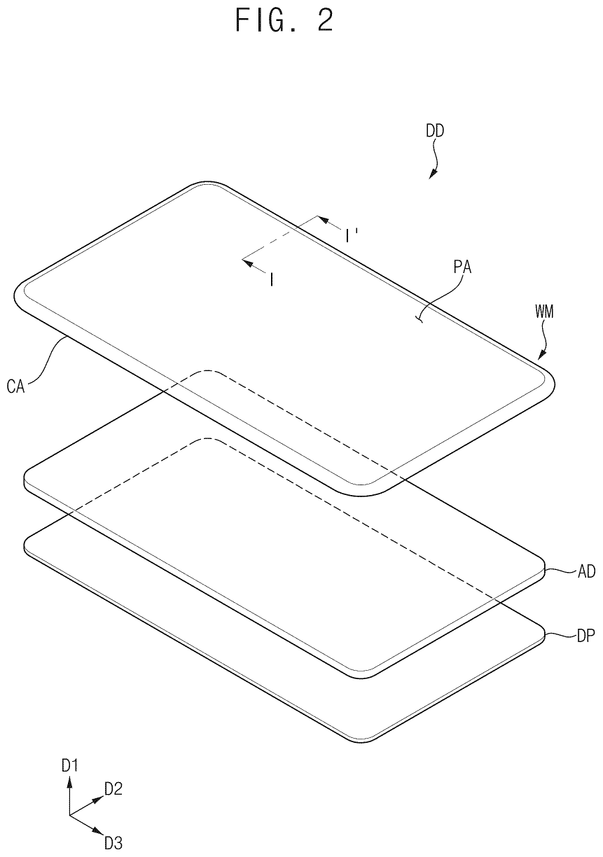

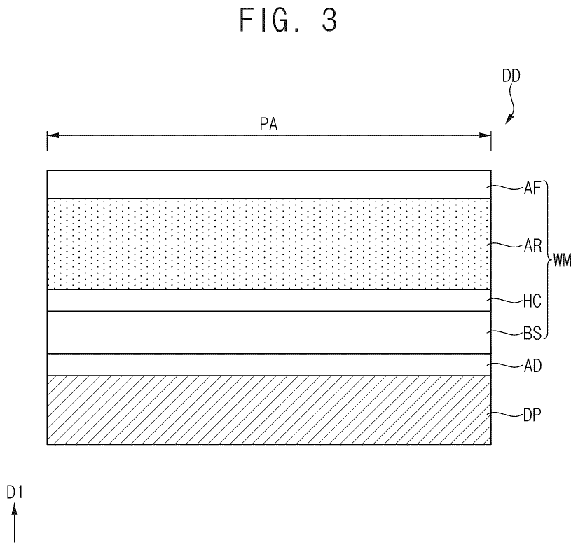

FIG. 2 is an exploded perspective view illustrating a partial configuration of the display device according to an embodiment of the display device of FIG. 1. FIG. 3 is a cross-sectional view schematically illustrating the display device of FIG. 1.

Referring to FIGS. 2 and 3, the display device DD according to an embodiment of the present disclosure may include a display panel DP, an adhesive layer AD and a window module WM. In some aspects, the window module WM may include a base substrate BS, a hard coating layer HC, an anti-reflection layer AR and an anti-fingerprint layer AF.

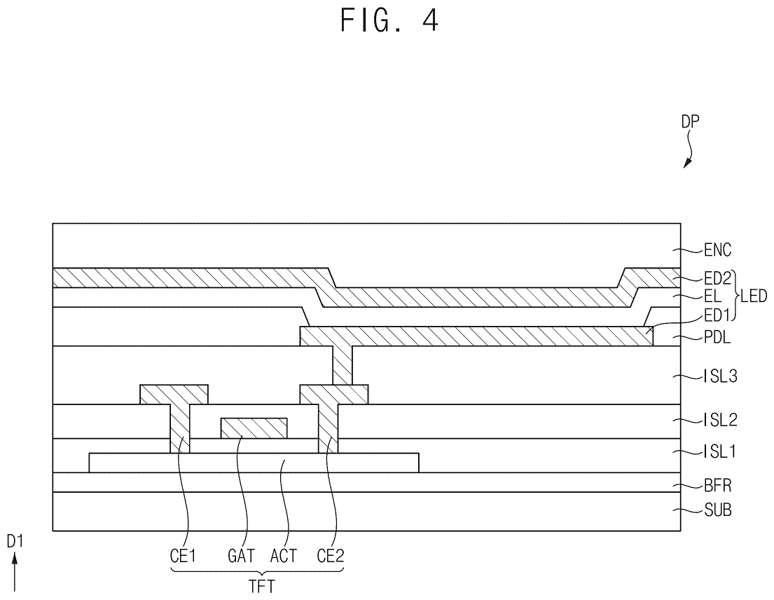

The display panel DP may display an image. For example, the display panel DP may include a transistor TFT (as illustrated in FIG. 4) and a light-emitting element LED (as illustrated in FIG. 4) electrically connected to the transistor TFT. The transistor TFT may provide a driving current to the light-emitting element LED, and the light-emitting element LED may emit light based on the driving current. A detailed description of the display panel DP will be described later with reference to FIG. 4.

In some aspects, although not illustrated in FIGS. 2 and 3, the display panel DP may include a bent portion corresponding to the shape of the window module WM.

As the display device DD includes the planar area PA and the curved area CA, the display panel DP may also include the planar area PA and the curved area CA. The planar area PA of the display panel DP may be an area capable of generating light or displaying an image by controlling a transmittance of light provided from an external light source. The curved area CA of the display panel DP may be an area that does not display an image. However, the embodiments of the present disclosure are not necessarily limited thereto and at least a portion of the curved area CA of the display panel DP may display an image.

The adhesive layer AD may be located on the display panel DP. The adhesive layer AD may include an adhesive material and may adhere the window module WM to the display panel DP. In an embodiment, the adhesive layer AD may include a pressure sensitive adhesive (PSA), an optically clear adhesive (OCA), an optically clear resin (OCR), and/or the like. These can be used alone or in combination with each other.

In some aspects, although not illustrated in FIGS. 2 and 3, the adhesive layer AD located below the window module WM may include a bent portion corresponding to the shape of the window module WM.

The base substrate BS may be located on the adhesive layer AD. In an embodiment, the base substrate BS may be formed of glass, quartz, plastic, or the like. Examples of the plastic which can be used as the base substrate BS may include polyimide (PI), polyethylene terephthalate (PET), polyethylene naphthalene (PEN), polypropylene (PP), polycarbonate (PC), polystyrene (PS), polysulfone (Psul), polyethylene (PE), polyphthalamide (PPA), polyethersulfone (PES), polyarylate (PAR), polycarbonate oxide (PCO), modified polyphenylene oxide (MPPO), and/or the like. These can be used alone or in combination with each other.

However, the base substrate BS is not limited to the materials described herein, and embodiments of the present disclosure may include using any material having optical transparency capable of providing an image provided on the display panel DP of the display device DD to a user without limitation.

The hard coating layer HC may be located on the base substrate BS. In an embodiment, the hard coating layer HC may be in contact with the base substrate BS. However, the present disclosure is not necessarily limited thereto, and an organic layer or an inorganic layer may be additionally located between the hard coating layer HC and the base substrate BS. The hard coating layer HC may protect the base substrate BS. To this end, the hard coating layer HC may have a predetermined hardness.

The hard coating layer HC may include a photocurable resin. The photocurable resin may be a polymer of a compound which has a polymerization reaction when irradiated with light such as, for example, ultraviolet rays, and a conventional one in the art may be used. For example, the photocurable resin may include acrylate oligomer, a multifunctional acrylate monomer, and/or the like. These can be used alone or in combination with each other.

The hard coating layer HC may further include fine particles dispersed in the photocurable resin. The fine particles dispersed in the photocurable resin may be organic or inorganic fine particles. For example, the fine particles may include organic fine particles such as, for example, acrylic resin, styrene resin, epoxide resin, nylon resin, and/or the like. These can be used alone or in combination with each other. Optionally, the fine particles may include metal oxide fine particles such as, for example, zirconium (Zr), titanium (Ti), indium (In), zinc (Zn), tin (Sn), aluminum (Al), antimony (Sb), and/or the like. These can be used alone or in combination with each other.

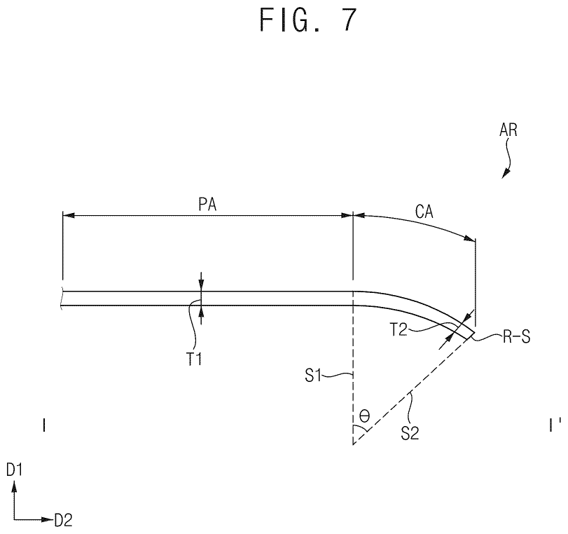

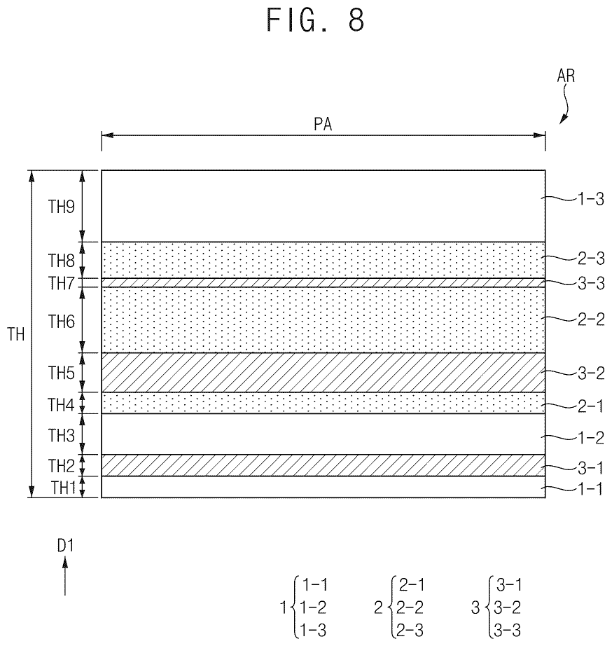

The anti-reflection layer AR may be located on the hard coating layer HC. In some aspects, the anti-reflection layer AR may reduce a reflectivity of the display panel DP. For example, the anti-reflection layer AR may suppress reflection of external light by stacking refractive layers having different refractive indices such that incident light and reflected light destructively interfere with each other. A detailed description of the anti-reflection layer AR may be described later with reference to FIGS. 7 and 8.

The anti-fingerprint layer AF may be located on the anti-reflection layer AR. In an embodiment, the anti-fingerprint layer AF may be formed by coating the anti-reflection layer AR with an anti-fingerprint material. Examples of the anti-fingerprint material which can be used as the anti-fingerprint layer AF may include metal oxide (e.g., titanium oxide (TiOx)), silicon-based compounds, fluorine-based compounds, and/or the like. These can be used alone or in combination with each other. However, the present disclosure is not necessarily limited thereto, and the anti-fingerprint material is not limited to any common material known to those skilled in the art. In some aspects, the coating method may include a wet coating method or a dry coating method. However, the present disclosure is not necessarily limited thereto.

FIG. 4 is a cross-sectional view illustrating a display panel included in the display device of FIG. 1.

Referring to FIG. 4, the display panel DP may include a substrate SUB, a buffer layer BFR, a transistor TFT, a first insulating layer ISL1, a second insulating layer ISL2, a third insulating layer ISL3, a pixel defining layer PDL, a light-emitting element LED, and an encapsulation layer ENC. The transistor TFT may include an active pattern ACT, a gate electrode GAT, a first connection electrode CE1, and a second connection electrode CE2. The light-emitting element LED may include a first electrode E1, an light emitting layer EL, and a second electrode E2.

In an embodiment, the substrate SUB may be formed of glass, quartz, plastic, or the like. Examples of the plastic which can be used as the substrate SUB include polyimide (PI), polyethylene terephthalate (PET), polyethylene naphthalene (PEN), polypropylene (PP), polycarbonate (PC), polystyrene (PS), polysulfone (Psul), polyethylene (PE), polyphthalamide (PPA), polyethersulfone (PES), polyarylate (PAR), polycarbonate oxide (PCO), modified polyphenylene oxide (MPPO), and/or the like. These can be used alone or in combination with each other.

The buffer layer BFR may be located on the substrate SUB. In an embodiment, the buffer layer BFR may include an insulating material. Examples of materials which can be used in the buffer layer BFR may include silicon oxide, silicon nitride, silicon oxynitride, and/or the like. These can be used alone or in combination with each other.

The active pattern ACT may be located on the buffer layer BFR. In an embodiment, the active pattern ACT may include an oxide semiconductor, a silicon semiconductor, or the like.

The first insulating layer ISL1 may be located on the buffer layer BFR and may cover the active pattern ACT. In an embodiment, the first insulating layer ISL1 may include an insulating material. Examples of materials which can be used as the first insulating layer ISL1 include silicon oxide, silicon nitride, silicon oxynitride, and/or the like. These can be used alone or in combination with each other.

The gate electrode GAT may be located on the first insulating layer ISL1 and may overlap with the active pattern ACT. In an embodiment, the gate electrode GAT may include a metal, an alloy, a conductive metal oxide, a transparent conductive material, or the like. Examples of materials which can be used as the gate electrode GAT include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These can be used alone or in combination with each other.

The second insulating layer ISL2 may be located on the first insulating layer ISL1 and may cover the gate electrode GAT. In an embodiment, the second insulating layer ISL2 may include an insulating material. Examples of materials which can be used as the second insulating layer ISL2 include silicon oxide, silicon nitride, silicon oxynitride, and/or the like. These can be used alone or in combination with each other.

The first connection electrode CE1 and the second connection electrode CE2 may be located on the second insulating layer ISL2 and may be in contact with the active pattern ACT. In an embodiment, the first connection electrode CE1 and the second connection electrode CE2 may include a metal, an alloy, a conductive metal oxide, a transparent conductive material, or the like. Examples of materials which can be used as the first connection electrode CE1 and the second connection electrode CE2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These can be used alone or in combination with each other.

The third insulating layer ISL3 may be located on the second insulating layer ISL2, and may cover the first connection electrode CE1 and the second connection electrode CE2. In an embodiment, the third insulating layer ISL3 may include an insulating material. Examples of materials which can be used as the third insulating layer ISL3 may include photoresist, polyacrylic resin, polyimide resin, acrylic resin, and/or the like. These can be used alone or in combination with each other.

The first electrode ED1 may be located on the third insulating layer ISL3 and may be in contact with the second connection electrode CE2. The pixel defining layer PDL may be located on the third insulating layer ISL3 and may include an opening exposing the first electrode ED1. The light emitting layer EL may be located on the first electrode ED1. The second electrode ED2 may be located on the light emitting layer EL.

The encapsulation layer ENC may be located on the second electrode ED2. The encapsulation layer ENC may prevent moisture and air from penetrating into the light-emitting element LED. In an embodiment, the encapsulation layer ENC may have a structure in which an inorganic insulating layer, an organic insulating layer, and an inorganic insulating layer are sequentially stacked.

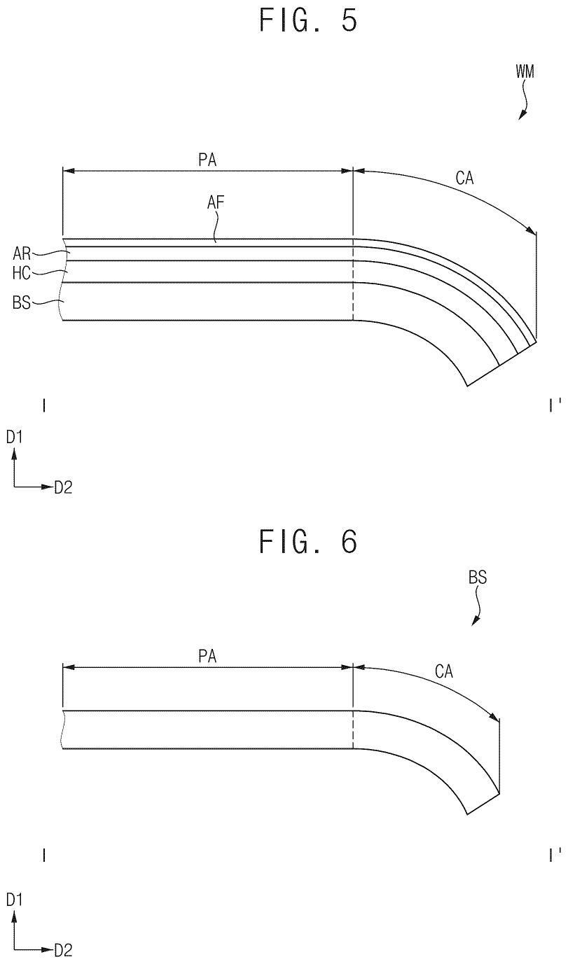

FIG. 5 is a cross-sectional view of a window module taken along the line I-I′ of FIG. 2. FIG. 6 is a cross-sectional view illustrating a base substrate of the window module of FIG. 5. FIG. 7 is a cross-sectional view illustrating an anti-reflection layer of the window module of FIG. 5.

Referring to FIG. 5, the window module WM according to an embodiment of the present disclosure may have a structure in which the base substrate BS, the hard coating layer HC, the anti-reflection layer AR, and the anti-fingerprint layer AF are sequentially stacked.

As described herein, the display device DD may include the planar area PA and the curved area CA. As the display device DD includes the planar area PA and the curved area CA, the window module WM may also include the planar area PA and the curved area CA.

Referring to FIG. 6, in an embodiment, the curved area CA of the base substrate BS may have a constant thickness overall. However, the present disclosure is not necessarily limited thereto. For example, the curved area CA of the base substrate BS may have a thickness which varies as the curved area CA gets farther away from the planar area PA.

Referring to FIG. 7, one end of the curved area CA of the anti-reflection layer AR may be defined as a boundary surface (hereinafter, “boundary surface”) between the planar area PA and the curved area CA. In this drawing, the boundary surface is illustrated by a dotted line. The other end of the curved area CA may be defined as a side surface R-S facing the boundary surface.

The anti-reflection layer AR may define a virtual first extension surface S1 extending the boundary surface and a virtual second extension surface S2 extending the side surface R-S.

In an embodiment, the curved area CA of the anti-reflection layer AR may have a thickness which varies as the curved area CA gets farther away from the planar area PA. For example, a thickness of the planar area PA adjacent to the boundary surface may be defined as a plane thickness T1. In some aspects, a thickness of the curved area CA adjacent to the side surface R-S may be defined as a curved thickness T2.

In an embodiment, the plane thickness T1 may be greater than the curved thickness T2. However, the present disclosure is not necessarily limited thereto.

In an embodiment, the curved thickness T2 may be defined according to the following Mathematical Formula 1.

$$T 2 = T 1 \times cos θ \qquad [ Mathematical Formula 1 ]$$

Here, θ is the angle formed by the virtual first extension surface S1 and the virtual second extension surface S2. For example, the angle (θ) may be less than or equal to about 45 degrees.

Accordingly, when depositing the anti-reflection layer AR, the curved thickness T2 of the curved area CA decrease compared to the plane thickness T1 of the planar area PA, and thus an optical path difference may occur in the curved area CA due to a change in film thickness. As a result, a color difference may occur in the curved area CA.

In an embodiment, the curved area CA of the window module WM may have a saturation (C*) of about 4 or less when θ is 45 degrees. The saturation (C*) may be defined according to the following Mathematical Formula 2.

$${C}^{*} = \sqrt{Δ {a}^{* 2} + Δ {b}^{* 2}} \qquad [ Mathematical Formula 2 ]$$

Here, C* is the saturation in the L*a*b color coordinate system, Δa is a difference in the Red-Green color direction in the L*a*b color coordinate system, and Δb* is a difference in the Yellow-Blue color direction in the L*a*b color coordinate system.

FIG. 8 is a cross-sectional view illustrating the anti-reflection layer of FIG. 3

Referring to FIG. 8, the anti-reflection AR may include nine refractive layers. In an embodiment, the anti-reflection layer AR may include a plurality of first refractive layers 1, a plurality of second refractive layers 2, and a plurality of third refractive layers 3.

The first refractive layers 1 may be located on the base substrate BS.

In an embodiment, the first refractive layers 1 may include a 1-1 refractive layer 1-1, a 1-2 refractive layer 1-2, and a 1-3 refractive layer 1-3.

In an embodiment, the first refractive layers 1 may be sequentially located as the 1-1 refractive layer 1-1, the 1-2 refractive layer 1-2, and the 1-3 refractive layer 1-3 on the base substrate BS.

The 1-1 refractive layer 1-1 may have a first thickness TH1. In an embodiment, the first thickness TH1 may have a range of about 20 nm to about 40 nm.

The 1-2 refractive layer 1-2 may have a third thickness TH3. In an embodiment, the third thickness TH3 may have a range of about 50 nm to about 70 nm.

The 1-3 refractive layer 1-3 may have a ninth thickness TH9. In an embodiment, the ninth thickness TH9 may have a range of about 95 nm to about 105 nm.

For visible light, the first refractive layers 1 may have a first refractive index. In an embodiment, the first refractive index may have a range of about 1.45 to about 1.5.

The first refractive layers 1 may include a first inorganic material. For example, the first inorganic material may include silicon dioxide (SiO₂), silicon oxide (SiOₓ), silicon oxynitride (SiOₓN_{y}), silicon aluminum oxide (SiₓAl_{y}O_{z}), magnesium fluoride (MgF₂), magnesium oxide (MgO), germanium oxide (GeOₓ), and/or the like. These can be used alone or in combination with each other. In an embodiment, the first refractive layers 1 may be silicon oxide (SiO₂).

The second refractive layers 2 may be located on the base substrate BS.

In an embodiment, the second refractive layers 2 may be located between the first refractive layers 1.

In an embodiment, the second refractive layers 2 may include a 2-1 refractive layer 2-1, a 2-2 refractive layer 2-2, and a 2-3 refractive layer 2-3.

In an embodiment, the second refractive layers 2 may be sequentially located as the 2-1 refractive layer 2-1, the 2-2 refractive layer 2-2, and the 2-3 refractive layer 2-3 on the base substrate BS.

The 2-1 refractive layer 2-1 may have a fourth thickness TH4. In an embodiment, the fourth thickness TH4 may have a range of about 20 nm to about 30 nm.

The 2-2 refractive layer 2-2 may have a sixth thickness TH6. In an embodiment, the sixth thickness TH6 may have a range of about 80 nm to about 100 nm.

The 2-3 refractive layer may have an eight thickness TH8. In an embodiment, the eight thickness TH8 may have a range of about 45 nm to about 55 nm.

For visible light, the second refractive layers 2 may have a second refractive index. In an embodiment, the second refractive index may have a range of about 1.95 to about 2.1.

The second refractive layers 2 may include a second inorganic material. For example, the second inorganic material may include silicon nitride (Si₃N₄), aluminum nitride (AlN), silicon aluminum nitride (SiAlₓN_{y}), germanium nitride (GeNₓ), silicon germanium nitride (SiGeₓN_{y}), tantalum pentoxide (Ta₂O₅), titanium dioxide (TiO₂), zirconium dioxide (ZrO₂), and/or the like. These can be used alone or in combination with each other. In an embodiment, the second refractive layers 2 may be silicon nitride (Si₃N₄).

The third refractive layers 3 may be located on the base substrate BS.

In an embodiment, the third refractive layers 3 may be located between the first refractive layers 1 and the second refractive layers 2.

In an embodiment, the third refractive layers 3 may include a 3-1 refractive layer 3-1, a 3-2 refractive layer 3-2, and a 3-3 refractive layer 3-3.

In an embodiment, the third refractive layers 3 may be sequentially located as the 3-1 refractive layer 3-1, the 3-2 refractive layer 3-2, and the 3-3 refractive layer 3-3.

The 3-1 refractive layer 3-1 may have a second thickness TH2. In an embodiment, the second thickness TH2 may have a range of about 20 nm to about 40 nm.

The 3-2 refractive layer 3-2 may have a fifth thickness TH5. In an embodiment, the fifth thickness TH5 may have a range of about 45 nm to about 65 nm.

The 3-3 refractive layer 3-3 may have a seventh thickness TH7. In an embodiment, the seventh thickness TH7 may have a range of about 5 nm to about 20 nm.

For visible light, the third refractive layers 3 may have a third refractive index. In an embodiment, the third refractive index may have a range of about 1.54 to about 1.7.

The third refractive layers 3 may include a third inorganic material. For example, the third inorganic material may include aluminum oxide (Al₂O₃), aluminum oxynitride (AlOₓN_{y}), silicon oxynitride (SiOₓN_{y}), silicon-aluminum oxynitride (SiAlₓO_{y}N₂), and/or the like. These can be used alone or in combination with each other. In an embodiment, the third refractive layers 3 may be silicon oxynitride (SiON).

In an embodiment, the 1-1 refractive layer 1-1, the 3-1 refractive layer 3-1, the 1-2 refractive layer 1-2, the 2-1 refractive layer 2-1, the 3-2 refractive layer 3-2, the 2-2 refractive layer 2-2, the 3-3 refractive layer 3-3, the 2-3 refractive layer 2-3, and the 1-3 refractive layer 1-3 may be sequentially located on the base substrate BS.

In an embodiment, the planar area PA of the anti-reflection layer AR may have a cross-sectional reflectance of about 1% or less. The cross-sectional reflectance is expressed as a percentage (%) of a rate at which a D65 standard light source is reflected from the surface of the anti-reflection layer AR.

In an embodiment, a thickness TH of the anti-reflection layer AR may have a range of about 400 nm to about 500 nm. At this time, if the thickness TH of the anti-reflection layer AR is less than 400 nm, a hardness of the window module WM may not be improved. If the thickness TH of the anti-reflection layer AR is greater than 500 nm, the color difference is not improved in the curved area CA of the window module WM, so red spots may appear.

In an embodiment, the second inorganic material and the third inorganic material may have a hardness greater than a hardness of the first inorganic material. For example, the third inorganic material may have a hardness greater than the hardness of the first inorganic material and a hardness less than a hardness of the second inorganic material. However, the present disclosure is not necessarily limited thereto.

In an embodiment, the hardness of the window module WM may have a range of about 10 GPa to about 15 GPa. Preferably, the hardness of the window module WM may have a range of about 12 GPa to about 15 GPa. More preferably, the hardness of the window module WM may have a range of about 13 GPa to about 15 GPa.

Hereinafter, effects of the present disclosure according to comparative example and embodiments will be described.

A window module including an anti-reflection layer according to a comparative example was manufactured. Referring to Table 1 below, the anti-reflection layer according to the comparative example was formed to have a seven-layer structure in which refractive layers formed of SiO₂ and refractive layers formed of Si₃N₄ were repeatedly stacked on a base substrate BS. At this time, a refractive index of SiO₂ is 1.48 and a refractive index of Si₃N₄ is 2.06.

TABLE 1

| Structure | Thickness (nm) |
|---|---|
| SiO₂ | 96.9 |
| Si₃N₄ | 57.7 |
| SiO₂ | 8.0 |
| Si₃N₄ | 78.1 |
| SiO₂ | 43.8 |
| Si₃N₄ | 18.5 |
| SiO₂ | 77.0 |

The window module WM including the anti-reflection layer AR according to embodiments 1 to 9 was manufactured. The anti-reflection layer AR is formed to have a structure in which the 1-1 refractive layer 1-1, the 3-1 refractive layer 3-1, the 1-2 refractive layer 1-2, the 2-1 refractive layer 2-1, the 3-2 refractive layer 3-2, the 2-2 refractive layer 2-2, the 3-3 refractive layer 3-3, the 2-3 refractive layer 2-3, and the 1-3 refractive layer 1-3 are sequentially stacked on the base substrate BS. The first refractive layers 1 including the 1-1 refractive layer 1-1, the 1-2 refractive layer 1-2, and the 1-3 refractive layer 1-3 have a refractive index of 1.48 and are formed of SiO₂. The second refractive layers 2 including the 2-1 refractive layer 2-1, the 2-2 refractive layer 2-2, and the 2-3 refractive layer 2-3 have a refractive index of 2.06 and are formed of Si₃N₄.

In embodiments 1 and 2, the third refractive layers 3 including the 3-1 refractive layer 3-1, the 3-2 refractive layer 3-2, and the 3-3 refractive layer 3-3 have a refractive index of 1.54 and are formed of SiON.

In embodiments 3 and 4, the third refractive layers 3 have a refractive index of 1.58 and are formed of SiON.

In embodiments 5 and 6, the third refractive layers 3 have a refractive index of 1.63 and are formed of SiON.

In embodiment 7, the third refractive layers 3 have a refractive index of 1.7 and are formed of SiON.

In embodiments 8 and 9, the third refractive layers 3 have a refractive index of 1.67 and are formed of Al₂O₃.

A thickness of each refractive layer of the anti-reflection layer is as illustrated in Table 2 below.

TABLE 2

| | Thickness (nm) | | | | | | | | |
|---|---|---|---|---|---|---|---|---|---|
| | Embodiment | | | | | | | | |
| Structure | 1 | 2 | 3 | 4 | 5 | 6 | 7 | 8 | 9 |
| 1-3 Refractive layer | 97.5 | 95.0 | 95.4 | 98.6 | 95.5 | 102.1 | 101.3 | 98.6 | 101.4 |
| 2-3 Refractive layer | 55.0 | 49.0 | 53.6 | 52.9 | 45.3 | 48.1 | 45.0 | 45.0 | 46.5 |
| 3-3 Refractive layer | 12.6 | 6.0 | 6.4 | 14.3 | 7.0 | 15.3 | 18.9 | 10.2 | 15.3 |
| 2-2 Refractive layer | 80.0 | 100.0 | 88.0 | 80.0 | 100.0 | 83.8 | 83.3 | 98.7 | 89.1 |
| 3-1 Refractive layer | 48.3 | 45.0 | 46.8 | 51.5 | 50.8 | 48.5 | 59.7 | 58.4 | 54.8 |
| 2-1 Refractive layer | 21.0 | 20.9 | 20.0 | 22.3 | 20.0 | 24.7 | 20.0 | 20.0 | 23.1 |
| 1-2 Refractive layer | 60.9 | 60.4 | 64.7 | 64.9 | 65.4 | 59.1 | 62.6 | 68.4 | 64.5 |
| 3-1 Refractive layer | 40.0 | 40.0 | 32.9 | 40.0 | 28.9 | 38.8 | 24.3 | 27.2 | 31.2 |
| 1-1 Refractive layer | 33.9 | 23.0 | 32.8 | 32.5 | 25.2 | 40.0 | 27.4 | 20.0 | 29.3 |

According to comparative example and embodiments 1 to 9, a hardness and a saturation of a curved area CA of the window module WM including the anti-reflection layer AR, and a cross-sectional reflectance and a thickness of the anti-reflection layer AR were measured.

The hardness is a value obtained by measuring a hardness of the planar area PA of the window module WM including the anti-reflection layer AR, the saturation of the curved area CA is a value obtained by measuring a saturation in the curved area CA according to L*a*b color coordinate system when θ is 40°, the cross-sectional reflectance is a value obtained by measuring a rate at which the D65 standard light source is reflected from the surface of the anti-reflection layer AR, and the thickness is a value obtained by measuring a thickness of the planar area PA of the anti-reflection layer AR.

TABLE 3

| | Cross-sectional | Saturation | | |
|---|---|---|---|---|
| | Reflectance | of the | Thickness | Hardness |
| | (%) | curved area | (nm) | (GPa) |
| Comparative | 0.81 | 2.7 | 380 | 12.2 |
| Example | | | | |
| Embodiment 1 | 0.95 | 2.7 | 450 | 14.6 |
| Embodiment 2 | 0.88 | 2.7 | 440 | 15.0 |
| Embodiment 3 | 0.73 | 2.7 | 440 | 14.9 |
| Embodiment 4 | 0.95 | 2.7 | 457 | 14.7 |
| Embodiment 5 | 0.77 | 2.7 | 440 | 15.0 |
| Embodiment 6 | 0.95 | 2.7 | 460 | 14.7 |
| Embodiment 7 | 0.95 | 2.7 | 442 | 14.7 |
| Embodiment 8 | 0.90 | 2.7 | 446 | 15.0 |
| Embodiment 9 | 0.95 | 2.7 | 455 | 14.9 |

As a result, referring to Table 3 above, it may be confirmed that the cross-sectional reflectance of the anti-reflection layer AR satisfying embodiments 1 to 9 is about 1% or less, the saturation of the curved area CA of the window module WM is about 2.7, the thickness of the anti-reflection layer AR is about 440 nm to about 460 nm, and the hardness of the window module WM is about 14 GPa to about 15 GPa. In contrast, it may be confirmed that the cross-sectional reflectance of the anti-reflection layer according to the comparative example is about 1% or less, the saturation of the curved area of the window module is about 2.7, the thickness of the anti-reflection layer is less than about 400 nm, and the hardness of the window module is less than about 14 GPa.

That is, the window module WM including the anti-reflection layer AR according to the embodiments of the present disclosure has the same saturation value of the curved area CA as the comparative example, and the cross-sectional reflectance is about 1% of less, which is also the same level of reflectance value as the comparative example. Accordingly, it may be confirmed that the embodiments have significantly lower curved area CA saturation values and cross-sectional reflectance values, which are the same level as the comparative example. In some aspects, the thickness and the hardness of the embodiments have increased values compared to the comparative example.

As a result, the window module WM of the present disclosure includes the anti-reflection layer AR including three first refractive layers having the first refractive index, three second refractive layers having the second refractive index higher than the first refractive index, and three third refractive layers having the third refractive index between the first refractive index and the second refractive index, such that the cross-sectional reflectance and the saturation of the curved area CA are maintained at the significantly lower levels of the comparative example, but the thickness of the anti-reflection layer AR is increased compared to the comparative example, thereby significantly improving the hardness of the window module WM.

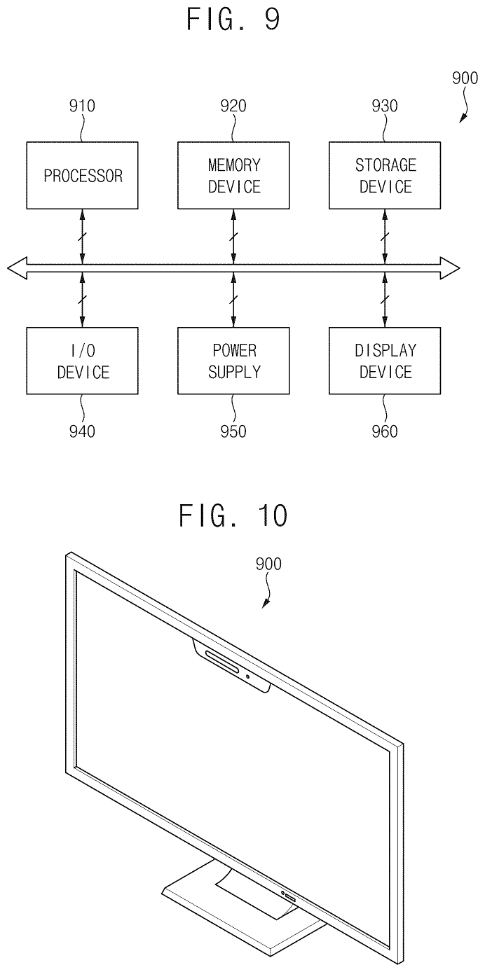

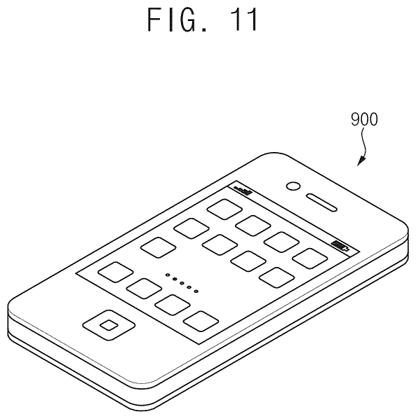

FIG. 9 is a block diagram illustrating an electronic device including the display device of FIG. 1. FIG. 10 is a diagram illustrating an example in which the electronic device of FIG. 9 is implemented as a television. FIG. 11 is a diagram illustrating an example in which the electronic device of FIG. 9 is implemented as a smartphone.

Referring to FIGS. 9, 10, and 11, in an embodiment, an electronic device 900 may include a processor 910, a memory device 920, a storage device 930, an input/output device 940, a power supply 950 and a display device 960. In this case, the display device 960 may correspond to the display device DD described with reference to FIGS. 1 to 8. The electronic device 900 may further include several ports capable of communicating with a video card, a sound card, a memory card, a USB device, or the like.

In an embodiment, as illustrated in FIG. 10, the electronic device 900 may be implemented as a television. In another embodiment, as illustrated in FIG. 11, the electronic device 900 may be implemented as a smartphone. However, the electronic device 900 is not necessarily limited thereto, and for example, the electronic device 900 may be implemented as a mobile phone, a video phone, a smart pad, a smart watch, a tablet PC, a vehicle navigation system, a computer monitor, a laptop, a head mounted display (HMD), or the like.

The processor 910 may perform specific calculations or tasks. The processor 910 may control the display device 960. In an embodiment, the processor 910 may be a microprocessor, a central processing unit (CPU), an application processor (AP), or the like. The processor 910 may be connected to other components via an address bus, a control bus, a data bus, or the like. The processor 910 may also be connected to an expansion bus, such as, for example, a peripheral component interconnect (PCI) bus.

The memory device 920 may store data for the operation of the electronic device 900. For example, the memory device 920 may include a nonvolatile memory device such as, for example, an erasable programmable read-only memory (EPROM) device, an electrically erasable programmable read-only memory (EEPROM), a flash memory device, a phase change random access memory (PRAM) device, a resistance random access memory (RRAM) device, a nano floating CEe memory (NFGM) device, a polymer random access memory (PoRAM) device, a magnetic random access memory (MRAM) device, a ferroelectric random access memory (FRAM) device, and/or a volatile memory device such as, for example, a dynamic random access memory (DRAM) device, a static random access memory (SRAM) device, a mobile DRAM device, or the like.

The storage device 930 may include a solid state drive (SSD), a hard disk drive (HDD), a CD-ROM, or the like.

The input/output device 940 may include input means such as, for example, a keyboard, a keypad, a touch pad, a touch screen, a mouse, or the like, and output means such as, for example, a speaker, a printer, or the like.

The power supply 950 may supply power for the operation of the electronic device 900. The display device 960 may be connected to other components via buses or other communication links. In an embodiment, the display device 960 may be included in the input/output device 940.

Although described herein with reference to example embodiments of the present disclosure, those of ordinary skill in the art will understand that the present disclosure may be variously modified and changed without departing from the spirit and scope of the present disclosure described in the following claims.

What is claimed is:

1. A window module comprising:
a base substrate; and
an anti-reflection layer comprising:
a plurality of first refractive layers located on the base substrate, comprising a first inorganic material, and having a first refractive index;
a plurality of second refractive layers located between the first refractive layers, comprising a second inorganic material, and having a second refractive index greater than the first refractive index; and
a plurality of third refractive layers located between the first refractive layers and the second refractive layers, comprising a third inorganic material, and having a third refractive index greater than the first refractive index and less than the second refractive index.

2. The window module of claim 1, wherein the first refractive index of each of the first refractive layers ranges from about 1.45 to about 1.5.

3. The window module of claim 1, wherein the second refractive index of each of the second refractive layers ranges from about 1.95 to about 2.1.

4. The window module of claim 1, wherein the third refractive index of each of the third refractive layers ranges from about 1.54 to about 1.7.

5. The window module of claim 1, wherein the first inorganic material comprises at least one selected from a group consisting of silicon dioxide (SiO₂), silicon oxide (SiOₓ), silicon oxynitride (SiOₓN_{y}), silicon aluminum oxide (SiₓAl_{y}O_{z}), magnesium fluoride (MgF₂), magnesium oxide (MgO), and germanium oxide (GeOₓ).

6. The window module of claim 1, wherein the second inorganic material comprises at least one selected from a group consisting of silicon nitride (Si₃N₄), aluminum nitride (AlN), silicon aluminum nitride (SiAlₓN_{y}), germanium nitride (GeNₓ), silicon germanium nitride (SiGeₓN_{y}), tantalum pentoxide (Ta₂O₅), titanium dioxide (TiO₂), and zirconium dioxide (ZrO₂).

7. The window module of claim 1, wherein the third inorganic material comprises at least one selected from a group consisting of aluminum oxide (Al₂O₃), aluminum oxynitride (AlOₓN_{y}), silicon oxynitride (SiOₓN_{y}), and silicon-aluminum oxynitride (SiAlₓO_{y}N_{z}).

8. The window module of claim 1, wherein the third inorganic material has a hardness greater than a hardness of the first inorganic material and less than a hardness of the second inorganic material.

9. The window module of claim 1, wherein:
the first refractive layers comprise:
a 1-1 refractive layer;
a 1-2 refractive layer located on the 1-1 refractive layer; and
a 1-3 refractive layer located on the 1-2 refractive layer,
the second refractive layers comprise:
a 2-1 refractive layer;
a 2-2 refractive layer located on the 2-1 refractive layer; and
a 2-3 refractive layer located on the 2-2 refractive layer, and the third refractive layers comprise:
a 3-1 refractive layer;
a 3-2 refractive layer located on the 3-1 refractive layer; and
a 3-3 refractive layer located on the 3-2 refractive layer.

10. The window module of claim 9, wherein the 1-1 refractive layer, the 3-1 refractive layer, the 1-2 refractive layer, the 2-1 refractive layer, the 3-2 refractive layer, the 2-2 refractive layer, the 3-3 refractive layer, the 2-3 refractive layer, and the 1-3 refractive layer are sequentially located on the base substrate.

11. The window module of claim 10, wherein:
a thickness of the 1-1 refractive layer ranges from about 20 nm to about 40 nm,
a thickness of the 1-2 refractive layer ranges from about 50 nm to about 70 nm,
a thickness of the 1-3 refractive layer ranges from about 95 nm to about 105 nm,
a thickness of the 2-1 refractive layer ranges from about 20 nm to about 30 nm,
a thickness of the 2-2 refractive layer ranges from about 80 nm to about 100 nm,
a thickness of the 2-3 refractive layer ranges from about 45 nm to about 55 nm,
a thickness of the 3-1 refractive layer ranges from about 20 nm to about 40 nm,
a thickness of the 3-2 refractive layer ranges from about 45 nm to about 65 nm, and
a thickness of the 3-3 refractive layer ranges from about 5 nm to about 20 nm.

12. The window module of claim 1, wherein a thickness of the anti-reflection layer ranges from about 400 nm to about 500 nm.

13. The window module of claim 1, wherein a hardness of the window module ranges from about 10 GPa to about 15 GPa.

14. The window module of claim 1, wherein the base substrate comprises:
a planar area; and
a curved area located on at least one side of the planar area and having a predetermined curvature.

15. The window module of claim 1, further comprising:
a hard coating layer located between the base substrate and the anti-reflection layer; and
an anti-fingerprint layer located on the anti-reflection layer.

16. A display device comprising:
a display panel;
a window module located on the display panel; and
an adhesive layer attaching the display panel and the window module,
wherein the window module comprises:
a base substrate; and
an anti-reflection layer comprising:
a plurality of first refractive layers located on the base substrate, comprising a first inorganic material, and having a first refractive index;
a plurality of second refractive layers located between the first refractive layers, comprising a second inorganic material, and having a second refractive index greater than the first refractive index; and
a plurality of third refractive layers located between the first refractive layers and the second refractive layers, comprising a third inorganic material, and having a third refractive index greater than the first refractive index and less than the second refractive index, and having a thickness in a range of about 400 nm to about 500 nm.

17. The display device of claim 16, wherein:
the first refractive index of each of the first refractive layers ranges from about 1.45 to about 1.5,
the second refractive index of each of the second refractive layers ranges from about 1.95 to about 2.1,
the third refractive index of each of the third refractive layers ranges from about 1.54 to about 1.7,
the first inorganic material comprises at least one selected from a group consisting of silicon dioxide (SiO₂), silicon oxide (SiOₓ), silicon oxynitride (SiOₓN_{y}), silicon aluminum oxide (SiₓAl_{y}O_{z}), magnesium fluoride (MgF₂), magnesium oxide (MgO), and germanium oxide (GeOₓ),
the second inorganic material comprises at least one selected from a group consisting of silicon nitride (Si₃N₄), aluminum nitride (AlN), silicon aluminum nitride (SiAlₓN_{y}), germanium nitride (GeNₓ), silicon germanium nitride (SiGeₓN_{y}), tantalum pentoxide (Ta₂O₅), titanium dioxide (TiO₂), and zirconium dioxide (ZrO₂), and
the third inorganic material comprises at least one selected from a group consisting of aluminum oxide (Al₂O₃), aluminum oxynitride (AlOₓN_{y}), silicon oxynitride (SiOₓN_{y}), and silicon-aluminum oxynitride (SiAlₓO_{y}N_{z}).

18. The display device of claim 16, wherein:
the first refractive layers comprise:
a 1-1 refractive layer;
a 1-2 refractive layer located on the 1-1 refractive layer; and
a 1-3 refractive layer located on the 1-2 refractive layer,
the second refractive layers comprise:
a 2-1 refractive layer;
a 2-2 refractive layer located on the 2-1 refractive layer; and
a 2-3 refractive layer located on the 2-2 refractive layer, and
the third refractive layers comprise:
a 3-1 refractive layer;
a 3-2 refractive layer located on the 3-1 refractive layer; and
a 3-3 refractive layer located on the 3-2 refractive layer.

19. The display device of claim 18, wherein the 1-1 refractive layer, the 3-1 refractive layer, the 1-2 refractive layer, the 2-1 refractive layer, the 3-2 refractive layer, the 2-2 refractive layer, the 3-3 refractive layer, the 2-3 refractive layer, and the 1-3 refractive layer are sequentially located on the base substrate.

20. An electronic device comprising:
a display device; and
a processor which controls the display device,
wherein:
the display device comprises:
a display panel;
a window module located on the display panel; and
an adhesive layer attaching the display panel and the window module, and
the window module comprises:
a base substrate; and
an anti-reflection layer comprising:
a plurality of first refractive layers located on the base substrate, comprising a first inorganic material, and having a first refractive index;
a plurality of second refractive layers located between the first refractive layers, comprising a second inorganic material, and having a second refractive index greater than the first refractive index; and
a plurality of third refractive layers located between the first refractive layers and the second refractive layers, comprising a third inorganic material, and having a third refractive index greater than the first refractive index and less than the second refractive index.
